(19) United States
(12) Patent Application Publication
(10) Pub. No.: US 2021/0227729 A1
(43) Pub. Date: Jul. 22, 2021

(54) MANUFACTURING METHOD FOR ELECTROMAGNETIC SHIELDING FILM AND ELECTROMAGNETIC SHIELDING WINDOW

(71) Applicants: SVG TECH GROUP CO., LTD, Jiangsu (CN); Soochow University, Jiangsu (CN)

(72) Inventors: Yanhua Liu, Jiangsu (CN); Linsen Chen, Jiangsu (CN); Bo Wang, Jiangsu (CN); Yue Shen, Jiangsu (CN); Yun Zhou, Jiangsu (CN); Xiaohong Zhou, Jiangsu (CN); Yan Ye, Jiangsu (CN); Zongbao Fang, Jiangsu (CN)

(21) Appl. No.: 16/096,781

(22) PCT Filed: May 16, 2017
(86) PCT No.: PCT/CN2017/084502

§ 371 Date: Oct. 26, 2018

(30) Foreign Application Priority Data
Jun. 14, 2016 (CN) 201610412201.1

(51) Int. Cl. H05K 9/00; B32B 17/10

(52) U.S. Cl. CPC H05K 9/0086; B32B 17/10981; B32B 2307/212; B32B 17/10165; B32B 17/10036; B32B 17/10889

(57) ABSTRACT

Provided is a method for manufacturing an electromagnetic shielding film, which includes: step 1), coating a photoresist on a conductive substrate, and then forming a pattern structure on the conductive substrate through a photolithography process; step 2), growing a metal layer in the pattern structure through a selective electrodeposition process to form a metal pattern structure; and step 3), embedding the metal pattern structure in a flexible base material through an imprinting process to form an electromagnetic shielding film. A method for manufacturing an electromagnetic shielding window is also provided.

The present application claims the priority to Chinese patent application No. 201610412201.1, titled “MANUFACTURING METHOD FOR ELECTROMAGNETIC SHIELDING FILM AND ELECTROMAGNETIC SHIELDING WINDOW” filed with the Chinese Patent Office on Jun. 14, 2016, which is incorporated herein by reference in its entirety.

### FIELD

The present disclosure relates to a film manufacturing technology, specifically to a method for manufacturing an electromagnetic shielding film and a method for manufacturing an electromagnetic shielding window.

### BACKGROUND

With the rapid development of the modem electronics industry, electronic products and wireless communication devices have been popularized, so that the application wavelength of electronic waves is continuously expanding, and the strength of the electronic waves is further increased, which makes the space electromagnetic environment increasingly complex. Electromagnetic radiation pollution has been paid more and more attention. Electromagnetic waves not only interfere with the normal operation of various electronic devices, and also threaten the information security of communication devices. In a severe situation, electromagnetic waves will also cause harm to human health. In order to prevent electromagnetic wave leakage causing electromagnetic hazard, currently, electromagnetic shielding materials are mainly used to shield electromagnetic waves.

Different requirements are imposed on the electromagnetic shielding effectiveness in different application fields. For industrial or commercial electronic equipment, the shielding effectiveness is generally required to be in a range from 30 dB to 60 dB. In the transparent electromagnetic shielding material used for the cathode tube ray display CRT, the sheet resistance is required to be less than 300 Ω/sq, and the corresponding electromagnetic shielding effectiveness is more than 30 dB. In the optical transparent shielding material of the plasma display PDP, the surface sheet resistance is required to be less than 2.5 Ω/sq, and the corresponding electromagnetic shielding effectiveness is more than 70 dB. At present, the electromagnetic shielding solution based on the metal grid can realize a better electromagnetic shielding effect and a certain optical transmittance.

With the development of science and technology, especially in the field of aerospace equipment, higher electromagnetic shielding requirements are proposed for transparent optical devices such as optical windows. The shielding effectiveness of electromagnetic shielding materials in the microwave frequency band should reach 60 dB to 90 dB, which can be applied to the shielding of aerospace and military equipment, and at the same time the optical transmittance is required to exceed 95%. It is required high light transmittance, high shielding effectiveness, good temperature resistance and low impact on optical imaging quality.

Chinese Patent No. 200610084149.8 titled “ELECTROMAGNETIC SHIELDED FILM AND ITS MANUFACTURING METHOD” discloses that a metal layer is plated by a vacuum sputtering and then thicken by an electrolytic plating process, and an electromagnetic shielding film with a metal grid pattern is forms by a photolithography technology. The wire diameter of the metal grid is 30 um and the thickness of the metal layer is 3.5 um.

Chinese Patent No. 201410745168.5 titled “PREPARATION METHOD OF WIRE MESH TRANSPARENT ELECTROMAGNETIC SHIELDING LAYER MATERIAL” discloses an electromagnetic shielding layer prepared by compositing a wire mesh and a PET membrane. The average diameter of the mesh is 35 μm and the spacing is 300 μm, realizing a transparent electromagnetic shielding film with a transmittance of 50% and an electromagnetic shielding effectiveness of 25 dB to 46 dB.

Chinese Patent No. 201010533228.9 titled “TRANSPARENT CONDUCTIVE FILM AND MANUFACTURING METHOD THEREOF” discloses a transparent conductive film prepared by a nano-imprinting and a nano-coating method. A groove is formed by nano-imprinting, nano-conductive material is filled in the groove, and then a high-performance conductive film, which can be used for fabricating an electromagnetic shielding film, is formed by sintering. During the sintering process of the nano-conductive material, the organic solvent volatilizes, and the metal particles in the conductive material aggregate to form a conductive grid structure. In this solution, the conductive material is sintered at a low temperature, and the contact resistance between the metal particles is large, so that the conductivity of the grid structure is affected (the conductivity is lower than that of the grid formed by deposition), thereby affecting the electromagnetic shielding effectiveness of the film produced by this solution.

Chinese Patent No. 201410464874.2 titled “ELECTROMAGNETIC SHIELDING CASE BASED ON MICRO METAL GRID AND MANUFACTURING METHOD OF ELECTROMAGNETIC SHIELDING CASE” discloses that a conductive grid structure is formed through conductive paste filling technology, then a micro metal grid is formed by electroforming deposition, and finally the metal grid is stripped to form a hollowed-out structure and extended to a concave die to make an electromagnetic shielding case. When using the blade coating technique to form the conductive grid pattern, the width of the grid groove is generally 5 μm or more, due to the influence of the particle size of the conductive paste. And the micro metal grid of the electromagnetic shielding case made by the solution is a convex structure.

Chinese Patent NO. 200810063988.0 titled “ELECTROMAGNETIC SHIELDING OPTICAL WINDOW WITH DOUBLE-LAYER PANE METAL GRIDDING STRUCTURE” proposes that double-layer metal grids with the same structural parameters are placed in parallel on both sides of the transparent substrate to form an electromagnetic shielding optical window, which can guarantee improving the electromagnetic shielding effectiveness while not reducing the transmittance. Chinese Patent No. 201410051541.7 titled “ELECTROMAGNETIC SHIELDING OPTICAL WINDOW BASED ON TRIANGULARLY-DISTRIBUTED TANGENT CIRCULAR RING AND INTERNALLY-TANGENT SUB CIRCULAR RING ARRAY”, Chinese Patent No. 201410052260.3 titled “ELECTROMAGNETIC SHIELDING LIGHT WINDOW BASED ON MULTI-CYCLE METAL RING TWO-DIMENSIONAL ORTHOGONAL NESTED ARRAY” disclose a specially designed ring pattern to realize a metal grid optical shielding window, in order to eliminate the influence of high-order diffraction light of the metal grid on imaging quality and detection results. The fabrication of the metal grid is accomplished by vacuum sputtering, mask exposure and etching technology. Vacuum coating and etching are used in all the above techniques, so that the line width is hardly lower than 30 μm.

For the process of compositing wire mesh and PET, the wire diameter is generally more than several tens of micrometers, which is difficult to realize a high transmittance electromagnetic shielding film. For the metal grid shielding film formed by photolithography and etching process, to achieve high shielding effectiveness, the metal grid layer is thickened by electroless plating or electroplating, after the metal grid is obtained by the etching process. At this time, the deposited metal layer belongs to “free growth”, causing the grid wire diameter to be seriously widened and affecting the optical transmittance. The vacuum coating process is required in the process, the etching process is complicated, and the production cost is high, which is not suitable for the low-cost requirement of mass production. The electromagnetic shielding film produced based on the metal grid is composited by a metal grid and a flexible substrate, and the thickness of the obtained shielding film is generally more than 50 um. This makes it difficult to attach the shielding film to a complicated structural surface, especially in the situation where multiple micro-scale films are required to be stacked, which causes many defects. At the same time, in many electromagnetic shielding applications, there are also stringent requirements on the temperature resistance of the film, such as up to 200° C. In addition, when the shielding film is applied to devices such as wearable electronics, smart phones and ultra-thin notebook computers, the bending radius of the shielding film is required to be less than 5 mm. In the past, the metal grid structure was attached to the surface of the flexible substrate. At this bending radius, the metal grid structure was easily separated from the flexible substrate, which was difficult to meet the application requirements in the field of flexible electronics.

### SUMMARY

To solve the above technical problems, a method for manufacturing an electromagnetic shielding film and electromagnetic shielding window with high transparency and good temperature resistance is provided in the present disclosure, which can meet the requirements of optical window for electromagnetic shielding film with high shielding performance, high image quality and high temperature resistance, the requirement of flexible electrons for bending performance of electromagnetic shielding film (bending radius less than 5 mm) and the requirement of complex structure surface bonding for the ultra-thinness of shielding film (the shielding film thickness is only a few micrometers).

To realize the above objects, following technical solutions are provided according to the present disclosure.

A method for manufacturing an electromagnetic shielding film includes:
step 1), coating a photoresist on a conductive substrate, and then forming a pattern structure on the conductive substrate through a photolithography process;
step 2), growing a metal layer in the pattern structure through a selective electrodeposition process to form a metal pattern structure; and
step 3), embedding the metal pattern structure in a flexible base material through an imprinting process to form an electromagnetic shielding film.

Furthermore, the step 3) includes:
coating a polyimide solution on the conductive substrate;
forming a film through thermal curing; and
separating the film and the conductive substrate to obtain the electromagnetic shielding film.

Optionally, the step 3) includes:
coating an ultraviolet curing adhesive on the conductive substrate, and covering a PET film on the ultraviolet curing adhesive;
irradiating the ultraviolet curing adhesive with an ultraviolet lamp, where the ultraviolet curing adhesive is cured and is adhered onto the PET film after irradiation; and
separating the PET film and the conductive substrate to obtain the electromagnetic shielding film.

Optionally, the step 3) includes:
covering a COC film on the conductive substrate;
applying temperature and pressure on the COC film; and
separating the COC film and the conductive substrate to obtain the electromagnetic shielding film.

Furthermore, step 21) is further provided between the step 2) and the step 3), the step 21) includes:
placing the conductive substrate having the metal pattern structure into stripping liquid to strip the photoresist on the conductive substrate except for the metal pattern structure.

Furthermore, the pattern structure is a grid structure.

Furthermore, the grid structure has a periodic arrangement or a non-periodic arrangement.

Furthermore, the conductive substrate is a flexible substrate or a rigid substrate.

A method for manufacturing an electromagnetic shielding window includes:
step 1), coating a photoresist on a conductive substrate, and then forming a pattern structure on the conductive substrate through a photolithography process;
step 2), growing a metal layer in the pattern structure through a selective electrodeposition process to form a metal pattern structure; and
step 3), arranging the conductive substrate having the metal pattern structure between two pieces of glass to form an electromagnetic shielding window, or attaching the conductive substrate having the metal pattern structure to one piece of glass to form an electromagnetic shielding window.

Furthermore, the conductive substrate having the metal pattern structure is composited with a surface of a mold by a solvent adhesive layer, to be molded.

In the present disclosure, photolithography technology (laser direct writing and ultraviolet exposure), selective electrodeposition technology and nano-imprinting technology (hot imprinting and film inversion technology) are used to manufacture the electromagnetic shielding film. The electromagnetic shielding film includes a metal grid structure layer having a line width of 300 nm to 10 μm, a grid spacing of 1 μm to 500 μm and a thickness of 300 nm to 10 μm, and a flexible substrate layer. The metal grid structure layer is embedded in the flexible substrate. Alternatively, the metal grid structure layer is embedded in an ultraviolet curing adhesive layer and is adhered to the flexible substrate layer by the ultraviolet curing adhesive layer.

Since the metal grid structure layer is formed by a deposition process, the surface sheet resistance of the transparent electromagnetic shielding film and the electromagnetic shielding window made according to the disclosure is only 0.05 Ω/sq to 0.4 Ω/sq, and the electromagnetic shielding effectiveness can reach 60 dB or more. In the disclosure, the deposition of the metal layer belongs to “constrained growth” (constrained in a trench formed by photoresist), which achieves high shielding effectiveness while ensuring high transmittance, and the optical transmittance may exceed 95%. In the disclosure, a polyimide PI material is used to form the flexible substrate and to manufacture the electromagnetic shielding film having embedded metal grid. In addition to excellent optical transmittance and low surface sheet resistance, the outstanding features are described as follows. Since the micro-nano-scale metal grid is embedded in the PI flexible substrate or the cured adhesive, instead of adhering to the surface, the electromagnetic shielding film is not easily contaminated and scratched, and in the situation that the bending radius is less than 3 mm, the attenuation of the shielding film performance is less than 5% and the temperature resistance is up to 200° C.

Compared with the conventional art, the advantages of the present disclosure are as follows.

1) The electromagnetic shielding film according to the present disclosure is prepared by a film inversion process, and the thickness of the PI film is only several micrometers to a few ten micrometers, which may realize an ultra-thin electromagnetic shielding film.

2) In the disclosure, the electromagnetic shielding film prepared by a selective electrodeposition can produce a metal grid structure having a line width of several hundred nanometers to micrometers, and the metal grid is formed by deposition, thereby ensuring high transmittance (more than 95%) of the electromagnetic shielding film, and at the same time achieving high shielding performance (more than 60 dB).

3) A nano-imprinting technique or a hot imprinting technique are used to embed the metal grid in the trench of the curing adhesive or the base material, instead of adhering to the surface, which can realize the electromagnetic shielding film having a bending radius less than 3 mm and make the surface not easily contaminated and scratched.

4) Compared with the conventional art, the flexible and high-transparency electromagnetic shielding film according to the disclosure does not involve a vacuum evaporation process, which makes lower manufacturing cost and higher efficiency.

### BRIEF DESCRIPTION OF THE DRAWINGS

FIG. 1 is a schematic flow chart of an electromagnetic shielding film of the present disclosure;

FIG. 2a is a top view of an electromagnetic shielding film according to an embodiment of the preset disclosure;

FIG. 2b is a side view of an electromagnetic shielding film according to an embodiment of the preset disclosure;

FIG. 3 is a schematic structural diagram of an electromagnetic shielding film according to another embodiment of the present disclosure;

FIG. 4a is a schematic structural diagram of an electromagnetic shielding window according to an embodiment of the present disclosure;

FIG. 4b is a schematic structural diagram of an electromagnetic shielding window according to another embodiment of the present disclosure;

FIG. 4c is a schematic structural diagram of an electromagnetic shielding device according to an embodiment of the present disclosure; and

FIG. 5 is a schematic structural diagram of an electromagnetic shielding film having a non-periodic metal grid according to an embodiment of the present disclosure.

### DETAILED DESCRIPTION

Referring to the drawings, the preferred embodiments of the present disclosure will be described in detail below.

The technical solution of this embodiment is comprehensively described as follows. A micro metal grid is embedded in a PI material by a micro-nano processing technology, which is flexible, not easy to scratch, high temperature resistance, good transparency and strong electromagnetic shielding effectiveness. Specific technical design is as follows. A grid structure is formed on a conductive substrate (conductive substrate material such as metal, metallized flexible conductive film, ITO and FTO glass) by a photolithography technique (such as laser direct writing, ultraviolet exposure and electron beam exposure). A metal layer (such as nickel, copper, gold) is grew in the grid structure by a selective electrodeposition process. The metal grid structure is embedded into a flexible substrate material by a nano-imprinting technology (hot imprinting and film inversion technology) to form an electromagnetic shielding film.

The technical solution of this embodiment is specifically as follows.

1) A preset grid is fabricated on a conductive substrate. According to the performance requirements of the electromagnetic shielding film (such as light transmittance, shielding effectiveness and high diffraction order extinction), a layout of the grid structure (such as periodic arrangement of hexagonal honeycombs, squares, parallelograms and non-periodic arrangement of arbitrary polygons), a line width of the grid (from 300 nm to 10 μm), a spacing of the grid (from 10 μm to 500 μm) and other parameters are designed, and then a pattern structure is formed on the conductive substrate coated with a photoresist by a micro-nanostructure patterning technology (such as laser direct writing, ultraviolet exposure and electron beam exposure).

2) A metal grid layer is grew by selective deposition. The patterned conductive substrate is placed on a cathode of an electrodeposition bath, and a metal material to be deposited is placed on an anode of the electrodeposition bath. With selective deposition of the electrodeposition, the metal material is deposited in a trench of the grid where the conductive substrate is exposed, and no electrodeposited layer is formed in an area covered by the photoresist. By controlling current intensity (from 500 mA to 50 A) attached to the electrode, deposition time (from 20 s to 6000 s), distance between the cathode and the anode (from 20 mm to 300 mm) and so on, a deposition thickness (from 300 nm to 10 μm) of the metal material may be controlled.

3) An electromagnetic shielding film having embedded metal grid is fabricated. The conductive substrate of the deposited metal grid layer is placed into stripping liquid, the photoresist on the conductive substrate is striped and only the metal grid deposited on the conductive substrate is retained. Using nano-imprinting technique (such as hot imprinting and film inversion technique), the metal grid on the conductive substrate is embedded in a transparent and flexible substrate to form an electromagnetic shielding film.

4) The thickness of the deposited layer is affected by energization time, current intensity and electrode spacing, and the greater the thickness of the deposited layer is, the higher the conductivity is. The thickness (from 300 nm to 10 μm) of the deposited layer may be controlled by adjusting the parameters of the electrodeposition. The transmittance of the electromagnetic shielding film depends on the proportion (less than 5%) of the metal grid portion to the entire portion, the wire width (from 200 nm to 10 μm) of the grid is restricted by the trench, which can realize the production of electromagnetic shielding film with transmittance more than 95% and shielding effectiveness more than 60 dB.

5) An electromagnetic shielding film is formed by a film inversion technology. Polyimide solution PI is coated on the deposited and stripped conductive substrate, after a film is formed by thermal curing, the film is separated from the conductive substrate and the thickness of the PI film is only a few micrometers to several ten micrometers (from 5 μm to 15 μm). The ultra-thin electromagnetic shielding film can be attached to a complex structure surface of any shape to produce an electromagnetic shielding device having complex topography requirements. At the same time, the electromagnetic shielding film has high temperature resistance.

6) An electromagnetic shielding film may be produced by a nano-imprinting technology. The ultraviolet curing adhesive is coated on the deposited and stripped conductive substrate, the PET film is covered on the ultraviolet curing adhesive, and the ultraviolet curing adhesive is irradiated with an ultraviolet lamp. The ultraviolet adhesive is cured and is adhered on the PET substrate after irradiation. The PET film is separated from the conductive substrate to obtain the metal grid type electromagnetic shielding film embedded in an ultraviolet curing adhesive.

7) An electromagnetic shielding film may be made by a hot imprinting technology. A COC film is covered on the deposited and stripped conductive substrate, and a certain temperature (exceeding the glass transition temperature of the COC film) and pressure are applied. The COC film and the conductive substrate are separated to obtain the electromagnetic shielding film embedded in the COC.

8) The substrate may be, but is not limited to, flexible films such as PI, PET, PEN, COC. Since the metal grid structure is embedded in the flexible substrate, the attenuation of the electromagnetic shielding effectiveness is less than 5% when the bending radius is less than 3 mm, and the film exhibits excellent scratch resistance.

Specific embodiments are described as follows.

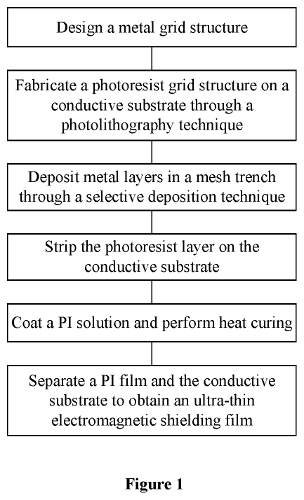

In a first embodiment, it is manufactured an ultra-thin metal grid electromagnetic shielding film. The production process is shown in FIG. 1. First, the layout of the metal grid structure, which maybe periodic arrangement of hexagonal honeycombs, squares, rectangles, parallelograms, triangles or arbitrary polygons arrangement, the line width of the grid (from 300 nm to 10 μm), the spacing of the grid (from 1 μm to 500 μm) and other parameters are designed based on the need of shielding effectiveness. Then a pattern grid structure is formed on the conductive substrate coated with the photoresist by patterning technology (such as laser direct writing, ultraviolet exposure and electron beam exposure). The patterned conductive substrate is placed on a cathode of the electrodeposition bath, and the metal material (such as nickel, copper, gold, aluminum and silver) to be deposited is placed on an anode of the electrodeposition bath. By the selective deposition of electrodeposition, the metal of the anode is gradually deposited in a conductive grid trench of the cathode by cations, and no electrodeposited layer is formed in the region covered by the photoresist. At this time, the sidewall of the photoresist trench on the conductive substrate has a certain depth (from 200 nm to 10 μm), then the deposition process of the cation is confined in the conductive trench of 300 nm to 10 μm, and the shape and line width of the conductive trench are the same as the shape and line width of the grid trench. By controlling the current intensity (from 500 mA to 20 A) attached to the electrode, the deposition time (from 20 s to 4000 s), the distance (from 20 mm to 300 mm) between the cathode and the anode, and so on, the deposition thickness (from 300 nm to 3 μm) of the metal material can be controlled. Subsequently, the conductive substrate of the deposited metal grid layer is placed into stripping liquid to strip the photoresist on the conductive substrate and only retain the metal grid deposited on the conductive substrate. Then, PI polyimide solution is coated on the conductive substrate and after a film is formed by thermal curing, the film is separated from the conductive substrate to obtain an ultra-thin metal grid electromagnetic shielding film.

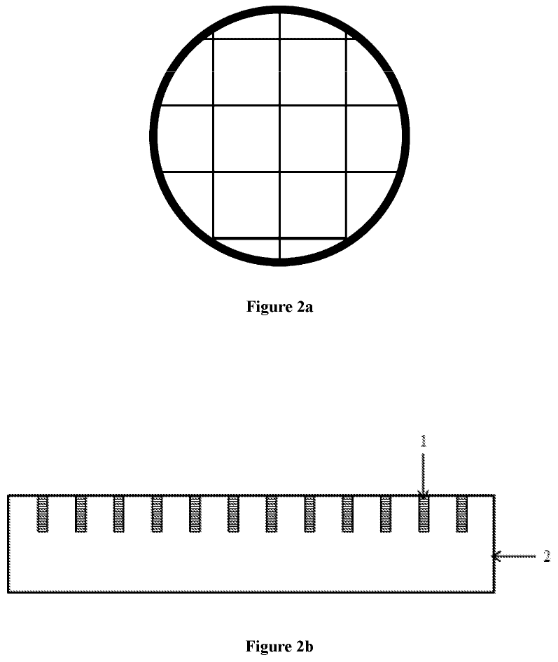

Depending on the coating method (such as spin coating, casting and blade coating), the thickness of the PI film can be adjusted. The thickness of the PI film is only several micrometers to a few ten micrometers (from 5 μm to 15 μm). FIG. 2a and FIG. 2b are top view and side view of the shielding film manufactured according to this method respectively. Since the metal grid structure 1 is embedded in the ultra-thin PI film 2, the shielding film may withstand a bend with a radius less than 20 μm. The metal material of the electromagnetic shielding film is a good conductor, such as nickel, copper, gold, aluminum and silver. The arrangement of the grid may be square, and in other embodiments may be a periodic arrangement of hexagons, rectangles or non-periodic arrangement. The ultra-thin electromagnetic shielding film can be attached to a complex structure surface of any shape to produce an electromagnetic shielding device having complex topography requirements.

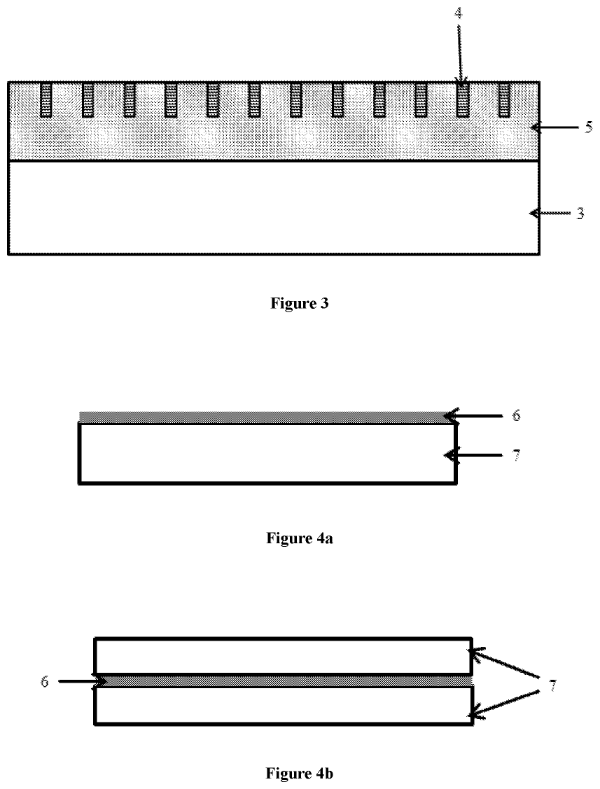

In a second embodiment, it is manufactured a metal grip type electromagnetic shielding film embedded in an ultraviolet curing adhesive. According to the production process of an embodiment, a metal grid structure is formed on the conductive substrate by a selective electrodeposition process. According to the design requirements, the line width (from 300 nm to 10 μm) of the metal grid, the spacing (from 10 μm to 500 μm) of the grid, and the thickness (from 300 nm to 10 μm) of the metal deposition layer are formed. Subsequently, an ultraviolet curing adhesive is coated on the deposited and stripped conductive substrate, the PET film is covered on the ultraviolet curing adhesive, and the ultraviolet curing adhesive is irradiated with an ultraviolet lamp. The ultraviolet adhesive is cured and is adhered on the PET substrate 3 after irradiation. After separating the PET film from the conductive substrate, the metal grid 4 is embedded in the ultraviolet curing adhesive 5 to form an electromagnetic shielding film, as shown in FIG. 3. The transmittance of the electromagnetic shielding film depends on the proportion (less than 5%) of the metal grid portion to the entire portion, and the width (from 300 nm to 10 μm) of the grid is restricted by the trench, so that the electromagnetic shielding film may achieve a transmittance more than 95% and a shielding effectiveness more than 60 dB.

In this embodiment, the used conductive substrate may be as a flexible or rigid substrate. In a case that a flexible conductive substrate (such as flexible metal plate and metalized flexible film) is used, a roll-to-roll nano-imprinting method can be adopted in the process of transferring the metal grid structure to the PET substrate, which is more suitable for the production of electromagnetic shielding films with large image, high transmittance and high shielding effectiveness.

In a third embodiment, it is manufactured an embedded electromagnetic shielding film. According to the production process of an embodiment, a metal grid structure is formed on the conductive substrate by a selective electrodeposition process. According to the design requirements, the line width (from 300 nm to 10 μm) of the metal grid, the spacing (from 10 μm to 500 μm) of the grid, and the thickness (from 300 nm to 10 μm) of the metal deposition layer are formed. And then, a COC film is covered on the deposited and stripped conductive substrate, and a certain temperature (exceeding the glass transition temperature of COC film) and pressure are applied. The metal grid is embedded in the COC film by a hot imprinting technology. The COC film and the conductive substrate are separated to obtain the electromagnetic shielding film embedded in the COC;

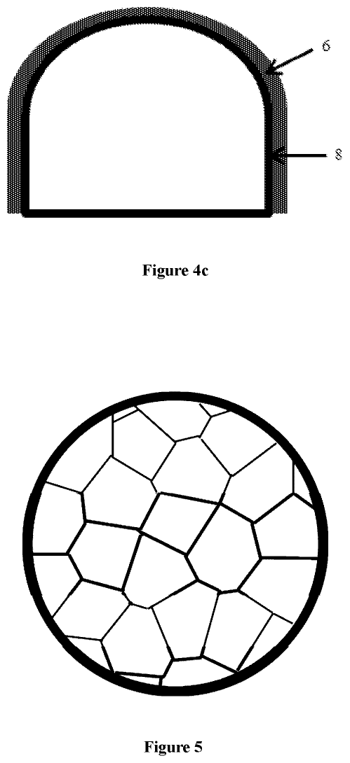

In a fourth embodiment, it is manufactured a hollowed-out metal grid electromagnetic shielding film. According to the production process of an embodiment, a metal grid structure is formed on the conductive substrate by a selective electrodeposition process. According to the design requirements, the line width (from 1 μm to 10 μm) of the metal grid and the spacing (from 1 μm to 500 μm) of the grid are formed. In order to separate the hollowed-out metal grid from the conductive substrate, the thickness of the metal grid should exceed 1 μm. The hollowed-out metal grid 6 may be arranged between two pieces of glass or may be attached to the glass 7 to form an electromagnetic shielding window, as shown in FIG. 4a and FIG. 4b. In addition, as shown in FIG. 4c, the hollowed-out metal grid 6 may be composited with a surface 8 of a mold having any other shape (such as concave, convex and irregular shapes) by a solvent adhesive layer, to form a special-shaped electromagnetic shielding device.

When the metal grid electromagnetic shielding film based on the first embodiment, the second embodiment, the third embodiment and the fourth embodiment is used to realize the optical shielding window, since the line width of the metal wire grid is generally on the order of micrometer or even sub-micrometer, the structure has a strong diffraction effect on the visible light. The zeroth order diffraction light and the high-order diffraction light coexist in the transmitted light. In order to eliminate the interference of the high-order diffraction light on the imaging and detection results, the arrangement of the metal grid can be designed as, for example, a polygonal arrangement of a non-periodic structure, uniform random arrangement in all directions. FIG. 5 is a schematic structural diagram of a non-periodic polygon sequence. At this time, the high-order diffraction light is eliminated, only the zeroth order transmitted light exists, which reduces the influence on the image quality.

The above is only a preferred embodiment of the present disclosure, and it should be noted that the person skilled in the art can make various modifications and improvements without deviating from the concept of the disclosure, and these modifications and improvements are also deemed to fall into the protection scope of the present disclosure.

1. A method for manufacturing an electromagnetic shielding film, comprising:
step 1), coating a photoresist on a conductive substrate, and then forming a pattern structure on the conductive substrate through a photolithography process;
step 2), growing a metal layer in the pattern structure through a selective electrodeposition process to form a metal pattern structure; and
step 3), embedding the metal pattern structure in a flexible base material through an imprinting process to form an electromagnetic shielding film.

2. The method for manufacturing an electromagnetic shielding film according to claim 1, wherein the step 3) comprises:
coating a polyimide solution on the conductive substrate;
forming a film through thermal curing; and
separating the film and the conductive substrate to obtain the electromagnetic shielding film.

3. The method for manufacturing an electromagnetic shielding film according to claim 1, wherein the step 3) comprises:
coating an ultraviolet curing adhesive on the conductive substrate, and covering a PET film on the ultraviolet curing adhesive;
irradiating the ultraviolet curing adhesive with an ultraviolet lamp, wherein the ultraviolet curing adhesive is cured and is adhered onto the PET film after irradiation; and
separating the PET film and the conductive substrate to obtain the electromagnetic shielding film.

4. The method for manufacturing an electromagnetic shielding film according to claim 1, wherein the step 3) comprises:
covering a COC film on the conductive substrate;
applying temperature and pressure on the COC film; and
separating the COC film and the conductive substrate to obtain the electromagnetic shielding film.

5. The method for manufacturing an electromagnetic shielding film according to claim 1, wherein step 21) is further provided between the step 2) and the step 3), the step 21) comprises:
placing the conductive substrate having the metal pattern structure into stripping liquid to strip the photoresist on the conductive substrate except for the metal pattern structure.

6. The method for manufacturing an electromagnetic shielding film according to claim 1, wherein the pattern structure is a grid structure.

7. The method for manufacturing an electromagnetic shielding film according to claim 6, wherein the grid structure has a periodic arrangement or a non-periodic arrangement.

8. The method for manufacturing an electromagnetic shielding film according to claim 1, wherein the conductive substrate is a flexible substrate or a rigid substrate.

9. A method for manufacturing an electromagnetic shielding window, comprising:
step 1), coating a photoresist on a conductive substrate, and then forming a pattern structure on the conductive substrate through a photolithography process;
step 2), growing a metal layer in the pattern structure through a selective electrodeposition process to form a metal pattern structure; and
step 3), arranging the conductive substrate having the metal pattern structure between two pieces of glass to form an electromagnetic shielding window, or attaching the conductive substrate having the metal pattern structure to one piece of glass to form an electromagnetic shielding window.

10. The method for manufacturing an electromagnetic shielding window according to claim 9, wherein the conductive substrate having the metal pattern structure is composited with a surface of a mold by a solvent adhesive layer, to be molded.

11. The method for manufacturing an electromagnetic shielding film according to claim 2, wherein step 21) is further provided between the step 2) and the step 3), the step 21) comprises:
placing the conductive substrate having the metal pattern structure into stripping liquid to strip the photoresist on the conductive substrate except for the metal pattern structure.

12. The method for manufacturing an electromagnetic shielding film according to claim 3, wherein step 21) is further provided between the step 2) and the step 3), the step 21) comprises:
placing the conductive substrate having the metal pattern structure into stripping liquid to strip the photoresist on the conductive substrate except for the metal pattern structure.

13. The method for manufacturing an electromagnetic shielding film according to claim 4, wherein step 21) is further provided between the step 2) and the step 3), the step 21) comprises:
placing the conductive substrate having the metal pattern structure into stripping liquid to strip the photoresist on the conductive substrate except for the metal pattern structure.
